(19) United States
(12) Patent Application Publication
(10) Pub. No.: US 2015/0270477 A1
(43) Pub. Date: Sep. 24, 2015

(54) ACTUATOR

(71) Applicant: PANASONIC INTELLECTUAL PROPERTY MANAGEMENT CO., Osaka-shi, Osaka (JP)

(72) Inventors: Toshiaki Horie, Osaka (JP); Shinsuke Nakazono, Osaka (JP); Soichiro Hiraoka, Hyogo (JP); Kazuki Komaki, Osaka (JP); Akira Kurozuka, Osaka (JP); Yuta Yamamoto, Osaka (JP); Takehiro Kobayashi, Osaka (JP)

(21) Appl. No.: 14/436,104

(22) PCT Filed: Oct. 1, 2013
(86) PCT No.: PCT/JP2013/005837

§ 371 Date: Apr. 16, 2015

(30) Foreign Application Priority Data
Oct. 31, 2012 (JP) 2012-240190

(51) Int. Cl. H01L 41/09; H02N 11/00

(52) U.S. Cl. CPC H01L 41/0933; H02N 11/006

(57) ABSTRACT

An actuator includes a fixed frame, a pair of first vibrating portions, a movable frame, a pair of second vibrating portions, a movable portion, and a first monitor signal detector. Each of the first vibrating portions faces the inside of the fixed frame; and has a first end connected to the inside of the fixed frame, and a second end connected to the outside of the movable frame. Each of the second vibrating portions faces the inside of the movable frame; and has a first end connected to the inside of the movable frame, and a second end connected to the movable portion. The second vibrating portions extend in a direction orthogonal to a direction in which the first vibrating portions extend. The first monitor signal detector capable of detecting displacement of the movable frame is provided on a connection portion between the movable frame and the first vibrating portion.

### TECHNICAL FIELD

The present invention relates to an actuator used for a display device and the like.

### BACKGROUND ART

An actuator is in practical use for scanning luminous flux from a light source such as a laser and an LED. This type of actuator scans luminous flux one-dimensionally for a laser printer and a barcode reader; two-dimensionally for a vehicle-mounted radar and a projection-type display device.

FIG. 12 is a perspective view of conventional actuator 1. FIG. 13 is a plan view of the monitor structure of actuator 1. Actuator 1 includes fixed frame 2, a pair of first vibrating portions 3 and 4, movable frame 5, a pair of second vibrating portions 6 and 7, and movable portion 8. The first ends of first vibrating portions 3 and 4 are connected to the inside of fixed frame 2 and the second ends thereof are connected to the outside of movable frame 5. First vibrating portions 3 and 4 rotatably support movable frame 5. The first ends of second vibrating portions 6 and 7 are connected to the inside of movable frame 5 and the second ends thereof are connected to movable frame 8. Second vibrating portions 6 and 7 are disposed so as to be substantially orthogonal to first vibrating portions 3 and 4 and rotatably support movable portion 8. Note that the main face of movable portion 8 functions as a mirror surface. Movable frame 5 rotates around the X axis. The X axis passes through the substantial center of movable portion 8 along first vibrating portions 3 and 4. Movable portion 8 rotates around the Y axis. The Y axis passes through the center of movable portion 8 along second vibrating portions 6 and 7.

As shown in FIG. 13, second vibrating portions 6 and 7 are provided with monitor signal detectors 9 and drive electrodes 10, respectively. Monitor signal detector 9 is formed of a piezoelectric film or piezoresistance. Accordingly, rotation of second vibrating portions 6 and 7 causes monitor signal detector 9 to output an electric signal. This signal allows providing displacement information about movable portion 8 (refer to PTL 1, for example).

FIG. 14 is a perspective view of another conventional actuator 19. Actuator 19 includes fixed frame 13, a pair of first vibrating portions 14, movable frame 15, a pair of second vibrating portions 16, and movable portion 17. The first ends of first vibrating portions 14 are connected to the inside of fixed frame 13 and the second ends thereof are connected to the outside of movable frame 15. The first ends of second vibrating portions 16 are connected to the inside of movable frame 15 and the second ends thereof are connected to movable frame 17. Second vibrating portions 16 extend in the direction substantially orthogonal to first vibrating portions 14. Monitor portion 18 is provided on the rotation axis of movable frame 15. Monitor portion 18 on movable frame 15 can detect a failure in scanning luminous flux by movable portion 17 (refer to PTL 2 for example).

### CITATION LIST

### Patent Literature

PTL 1: Japanese Patent Unexamined Publication No. 2010-148265

PTL 2: Japanese Patent Unexamined Publication No. 2007-017648

### SUMMARY OF THE INVENTION

The present invention provides an actuator capable of accurately determining displacement information about the movable frame. An actuator of the present invention includes a fixed frame, a pair of first vibrating portions, a movable frame, a pair of second vibrating portions, a movable portion, and a first monitor signal detector. Each of the first vibrating portions faces the inside of the fixed frame; and has a first end connected to the inside of the fixed frame, and a second end connected to the outside of the movable frame. Each of the second vibrating portions faces the inside of the movable frame; and has a first end connected to the inside of the movable frame, and a second end connected to the movable portion. The second vibrating portions extend in a direction orthogonal to a direction in which the first vibrating portions extend. The first monitor signal detector is provided on the connection portion between the movable frame and the first vibrating portion and capable of detecting displacement of the movable frame. The above structure allows accurately determining displacement information about the movable frame. Accordingly, the actuator can be controlled highly accurately.

### BRIEF DESCRIPTION OF DRAWINGS

FIG. 1 is a perspective view of an actuator according to a first exemplary embodiment of the present invention.

FIG. 2 is a sectional view of the actuator shown in FIG. 1, taken along line 2-2.

FIG. 3 illustrates drive of a first vibrating portion of the actuator shown in FIG. 1.

FIG. 4A illustrates an operating state of a movable portion with respect to a movable frame of the actuator shown in FIG. 1.

FIG. 4B illustrates operating states of the movable frame and the movable portion with respect to a fixed frame of the actuator shown in FIG. 1.

FIG. 5 is an enlarged plan view of the movable frame and its periphery of the actuator shown in FIG. 1.

FIG. 6A illustrates displacement information about the movable portion and the movable frame of the actuator shown in FIG. 1.

FIG. 6B illustrates displacement information about the movable portion including that of the movable frame of the actuator shown in FIG. 1.

FIG. 6C is a block diagram illustrating the process of generating a drive signal of the actuator shown in FIG. 1.

FIG. 7 illustrates deformation of the movable frame while the actuator shown in FIG. 1 is being driven.

FIG. 8 is a perspective view of an actuator according to a second exemplary embodiment of the present invention.

FIG. 9 is an enlarged plan view of a movable frame and its periphery of the actuator shown in FIG. 8.

FIG. 10A illustrates displacement information about the movable frame of the actuator shown in FIG. 8 and a drive signal for damping vibration of the movable frame.

FIG. 10B illustrates displacement information about the movable frame with respect to a fixed frame of the actuator in FIG. 8.

FIG. 10C is a block diagram illustrating the process of generating a drive signal of the actuator shown in FIG. 8.

FIG. 11 is an enlarged plan view of a movable frame and its periphery of another actuator according to the second exemplary embodiment of the present invention.

FIG. 12 is a perspective view of a conventional actuator.

FIG. 13 is a plan view of the monitor structure of the actuator shown in FIG. 12.

FIG. 14 is a perspective view of another conventional actuator.

### DESCRIPTION OF EMBODIMENTS

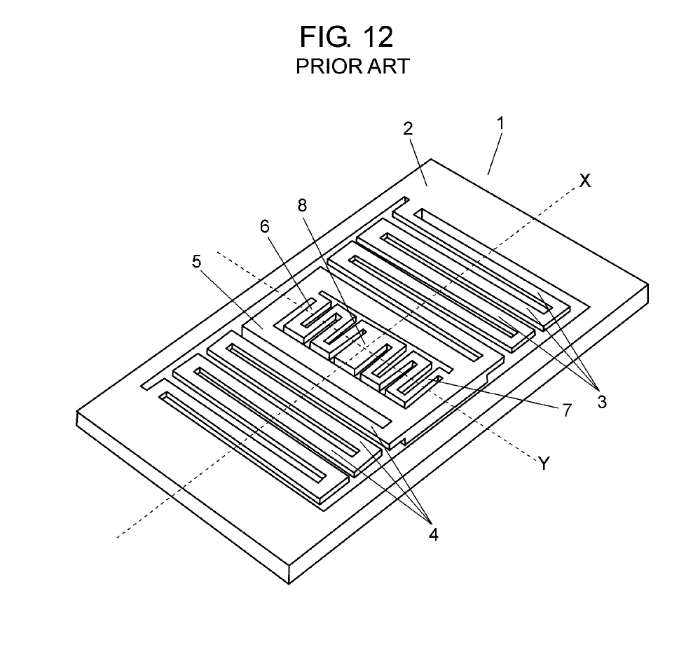

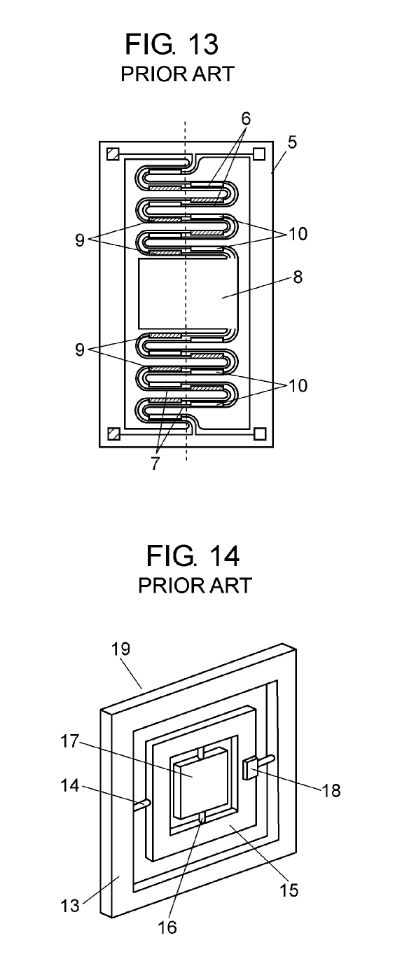

Prior to the description of embodiments of the present invention, a description is made of some problems in conventional actuators 1 and 19 shown in FIGS. 12 through 14. Actuator 1 is provided with monitor signal detectors 9 inside movable frame 5. This structure allows obtaining displacement information about movable portion 8 with respect to movable frame 5. When movable portion 8 rotates around the Y axis, however, monitor signal detectors 9 are unable to detect displacement information about movable frame 5 in spite of the fact that movable frame 5 as well rotates by counteraction. Accordingly, it is hard in actuator 1 to obtain accurate displacement information about movable portion 8.

On the other hand, actuator 19 is provided with monitor portion 18 on movable frame 15. This structure is unable to obtain displacement information about movable portion 17 and about movable frame 15, separately.

To control an actuator with a high degree of accuracy, however, displacement information about the movable portion with respect to the fixed frame, as well as displacement information about the movable portion with respect to the movable frame, needs to be detected to accurately determine displacement information about the movable portion with respect to the fixed frame. To use an actuator for a display device, for example, the main face of the movable portion functions as a mirror surface that reflects luminous flux. Then, output from a light source is controlled according to the position of the mirror surface so as to display images. For this reason, the position of the mirror surface with respect to the fixed frame needs to be detected highly accurately.

### First Exemplary Embodiment

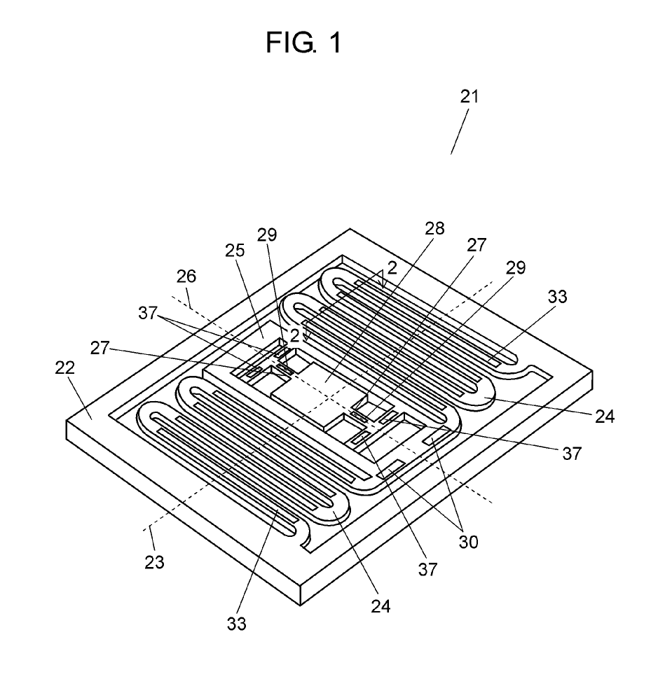

Hereinafter, a description is made of actuator 21 according to a first exemplary embodiment of the present invention with reference to the drawings. FIG. 1 is a perspective view of actuator 21 according to the first embodiment of the present invention. Actuator 21 includes fixed frame 22, a pair of first vibrating portions 24, movable frame 25, a pair of second vibrating portions 27, movable portion 28, and first monitor signal detectors (hereinafter, detectors) 30.

Each of first vibrating portions 24 faces the inside of fixed frame 22; and has a first end connected to the inside of fixed frame 22, and a second end connected to the outside of movable frame 25. First vibrating portion 24 is formed in a meandrous shape where linear-shaped vibrating beams and folded vibrating beams are alternately linked. Each of second vibrating portions 27 faces the inside of fixed frame 25; and has a first end connected to the inside of movable frame 25, and a second end connected to movable portion 28.

Second vibrating portions 27 extend in a direction orthogonal to a direction in which first vibrating portions 24 extend. In FIG. 1, first vibrating portions 24 extend along X axis 23 and second vibrating portion 27 extend along Y axis 26. Each of detectors 30 is provided on the connection portion between movable frame 25 and first vibrating portion 24 and is capable of detect displacement of movable frame 25.

Note that the main face of movable portion 28 being a mirror surface implements an optical reflecting element. The main face of movable portion 28 being a photo-reception surface implements an infrared detection element, for example. Each of second vibrating portions 27 is provided with second monitor signal detector (hereinafter, detector) 29 capable of detecting a drive mode (displacement) of respective second vibrating portions 27.

Each of first vibrating portions 24 is provided with first driver 33 configured to control displacement of first vibrating portion 24. Each of second vibrating portions 27 is provided with second driver 37 configured to control displacement of second vibrating portion 27.

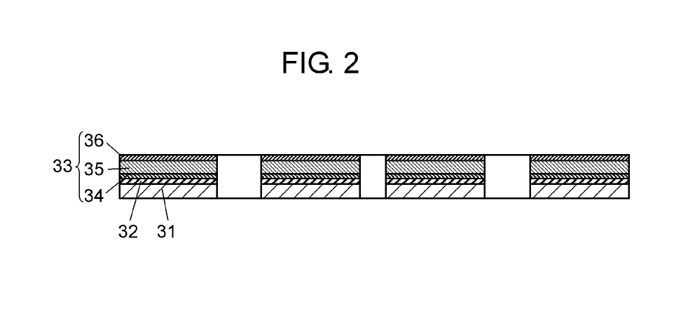

FIG. 2 is a sectional view of actuator 21 shown in FIG. 1, taken along line 2-2. First vibrating portion 24 has substrate 31, and insulator 32 formed on substrate 31. First driver 33 is formed on insulator 32.

First driver 33 is composed of lower electrode 34, piezoelectric body 35 formed on lower electrode 34, and upper electrode 36 formed on piezoelectric body 35. Lower electrode 34 and upper electrode 36 are formed of a metal film such as platinum, gold, titanium, and tungsten. Piezoelectric body 35 is formed of a piezoelectric material such as lead zirconate titanate (Pb(Zr₁₋ₓ, Tiₓ)O₃). Lower electrode 34, piezoelectric body 35, and upper electrode 36 can be formed into a thin film by vapor deposition, sol-gel process, chemical vapor deposition (CVD), or sputtering, for example.

Applying an electric potential difference between lower electrode 34 and upper electrode 36 causes the inverse piezoelectric effect and extends and contracts piezoelectric body 35 in its planar direction. Accordingly, first driver 33 including piezoelectric body 35 causes bending displacement in the thicknesswise direction. At this moment, when electric fields are applied to adjacent vibrating beams of first vibrating portion 24 alternately in reverse directions, deformations caused along Y axis 26 are added with each other and rotates movable frame 25 containing movable portion 28 around X axis 23.

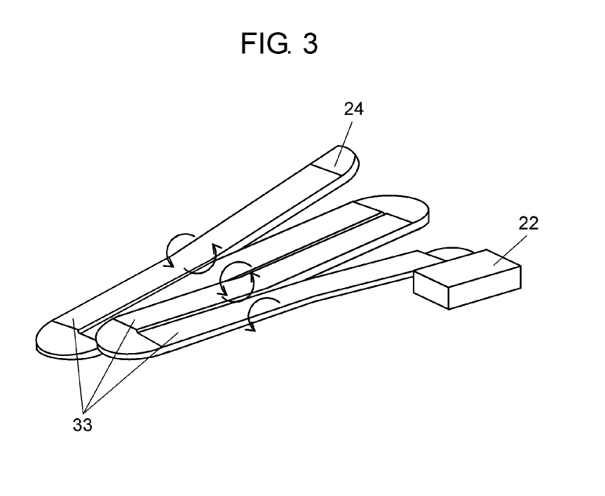

FIG. 3 illustrates drive of first vibrating portion 24 of actuator 21. As described above, by applying a given electric potential to first driver 33 so that adjacent, linear-shaped vibrating beams of first vibrating portion 24 are displaced in reverse directions, displacements of the vibrating beams are added with each other and largely displace-drive movable frame 25 as shown in FIG. 3.

Note that second driver 37 provided on second vibrating portion 27 is structured so that movable portion 28 rotates around Y axis 26 in the same way as first driver 33. In other words, as second drivers 37 are separately disposed centering around Y axis 26, applying electric fields to respective second drivers 37 in reverse directions exerts reverse bending moment on the vibration plates in the Y axial direction forming second vibrating portions 27. This bending moment helps second vibrating portions 27 twist easily, thereby largely displacing movable portion 28 centering around Y axis 26.

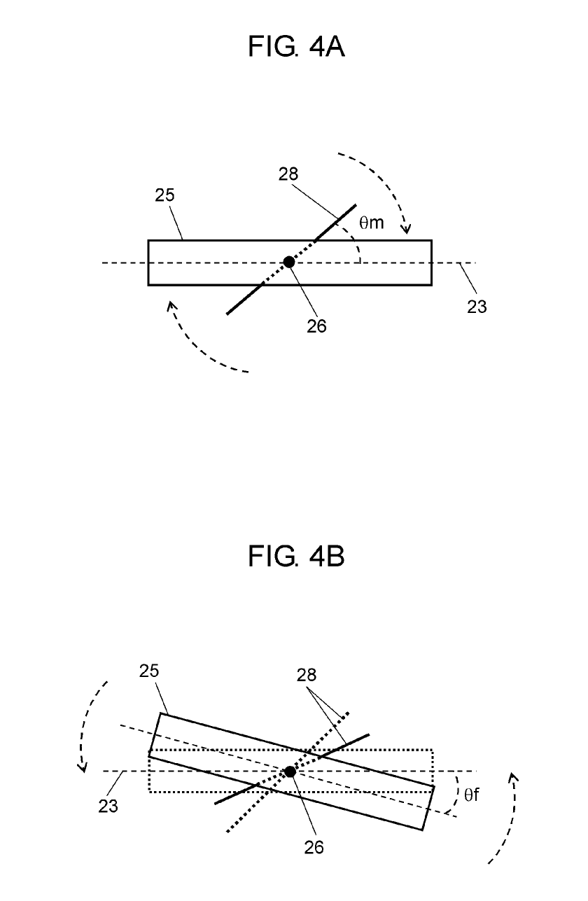

FIG. 4A illustrates an operating state of movable portion 28 with respect to movable frame 25. FIG. 4B illustrates operating states of movable frame 25 and movable portion 28 with respect to fixed frame 22. In these figures, the plane formed by X axis 23 and Y axis 26 is the main face direction of fixed frame 22. The solid line in FIG. 4B indicates operating states of movable frame 25 and movable portion 28 with respect to fixed frame 22. The broken line in FIG. 4B indicates an operating state of movable portion 28 with respect to movable frame 25 shown in FIG. 4A in an overlapped manner.

When movable portion 28 rotates, movable frame 25 rotates as well by counteraction. Specifically, the angle formed by fixed frame 22 and movable portion 28 is θm-θf, where θm is the angle formed by movable frame 25 and movable portion 28 and θf is the angle formed by fixed frame 22 and movable frame 25.

In a structure in which first driver 33 is integrally formed on first vibrating portion 24, it is known that a force from first driver 33 changes the rigidity of first vibrating portion 24. After all, movable frame 25 is supported by first vibrating portion 24, and applying a voltage to first driver 33 causes piezoelectric body 35 forming first driver 33 to extend and contract in the planar direction of piezoelectric body 35. Accordingly, a force from first driver 33 changes the rigidity of first vibrating portion 24, which changes the rotational state of movable frame 25. This makes it impossible to scan movable portion 28 with a desired waveform. For example, when laser light is reflected on movable portion 28 and is scanned to project images, they become distorted, and high-resolution images cannot be projected.

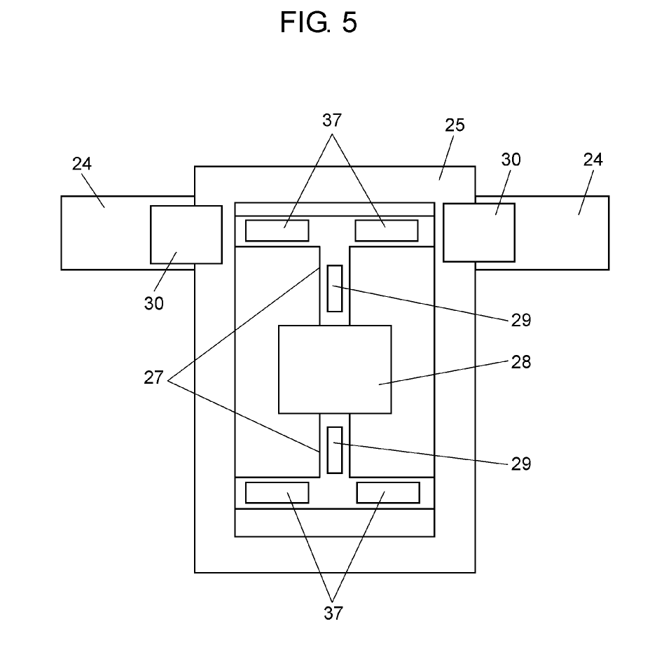

FIG. 5 is an enlarged plan view of movable frame 25 and its periphery. As described above, detectors 30 are provided on the connection portions between first vibrating portion 24 and movable frame 25, and detectors 29 are provided on second vibrating portions 27, respectively. Detectors 30 and 29 have the same cross-sectional structure as that of first vibrating portion 24 shown in FIG. 2. More specifically, detectors 30 and 29 are composed of a lower electrode formed on the insulator on substrate 31, a piezoelectric body formed on the lower electrode, and an upper electrode formed on the piezoelectric body. When detectors 30 and 29 strain, the piezoelectric body forming detectors 30 and 29 also strains, which generates a distortion signal due to the piezoelectric effect. Detecting a signal from detectors 29 allows detecting displacement information about second vibrating portions 27. Accordingly, displacement information about movable portion 28 can be determined by a detection signal from detectors 29.

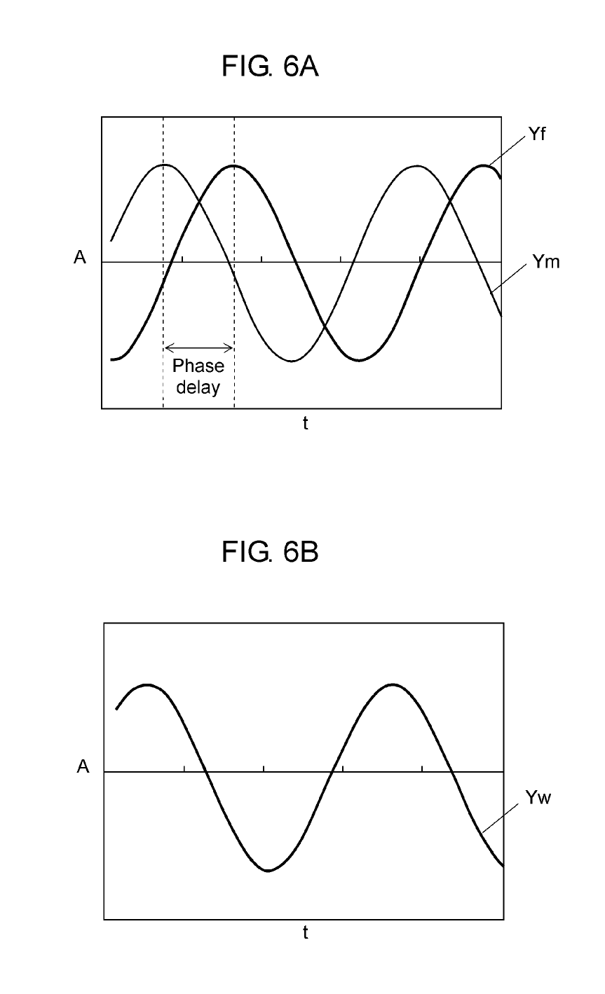

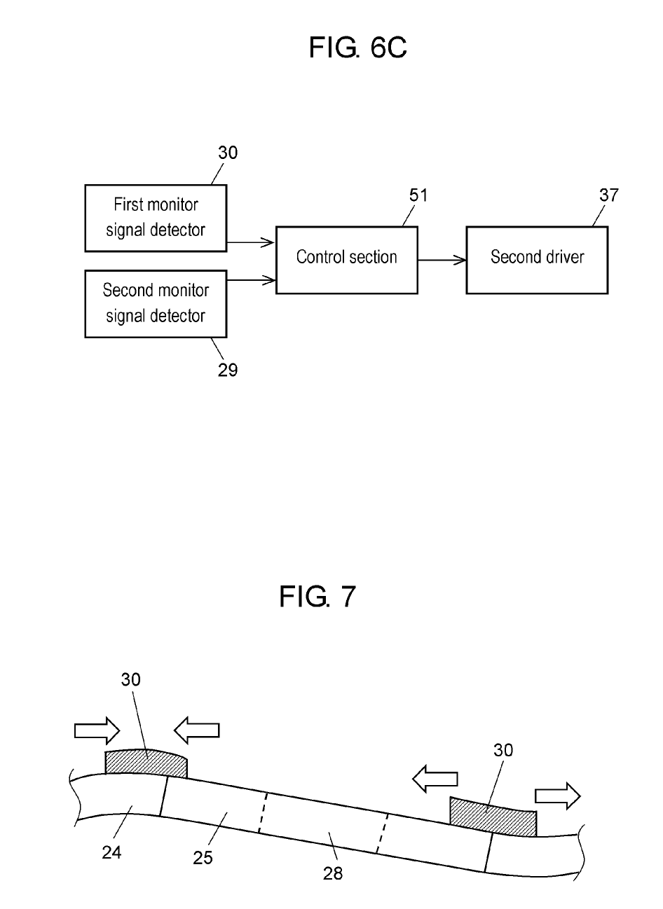

Next, a description is made of some advantages of providing detector 30, with reference to FIGS. 6A and 6B. FIG. 6A illustrates displacement information Yf about movable frame 25, and displacement information Ym about movable portion 28. FIG. 6B illustrates accurate displacement information Yw about movable portion 28 obtained by adding displacement information Yf about movable frame 25 to displacement information Ym about movable portion 28. As detector 30 is provided on the connection portion between first vibrating portion 24 and movable frame 25, displacement information about movable frame 25 with respect to fixed frame 22 can be determined.

Displacement information Ym about movable portion 28 with respect to movable frame 25, obtained from detector 29 is represented by formula (1). Meanwhile, displacement information Yf about movable frame 25 with respect to fixed frame 22, obtained from detector 30 is represented by formula (2). Then, compositing formula (1) with formula (2), as represented by formula (3), provides displacement information Yw about movable portion 28 with respect to fixed frame 22.

Ym=A sin(ωt+δm) (1)

Yf=B sin(ωt+δf) (2)

Yw=A sin(ωt+δm)±B sin(ωt+δf) (3)

Displacement information Yw represented by formula (3) is an accurate displacement of movable portion 28 with respect to fixed frame 22. In a case as well where movable portion 28 is controlled synchronously with an image signal for example, by generating a drive signal on the basis of displacement information Yw and inputting the drive signal into second driver 37, high-resolution images can be displayed without causing a phase shift between movable portion 28 and the image signal. This signal process can be performed by a circuit provided outside actuator 21. Alternatively, actuator 21 may be provided with control section 51 that generates a drive signal on the basis of displacement information Yw and inputs the signal into second driver 37 as shown in FIG. 6C. Note that displacement information Yw is obtained by “Yw=Ym−Yf” in FIG. 6B.

Detector 30 is provided on the connection portion between movable frame 25 and first vibrating portion 24 as shown in FIG. 5. With such a structure, a distortion signal can be obtained from the piezoelectric body forming detector 30 when movable frame 25 rotates. In a case, however, where detector 30 is provided only on first vibrating portion 24 so that detector 30 does not contain the boundary between movable frame 25 and first vibrating portion 24, a displacement state of first vibrating portion 24 is monitored and displacement information about movable frame 25 cannot be obtained. In another case, on the other hand, where detector 30 is provided only on movable frame 25 so that detector 30 does not contain this boundary, an insufficient intensity of a signal is obtained due to a small distortion of movable frame 25. Accordingly, detector 30 is disposed in a range where displacement caused by movable frame 25 is detectable, where it is desirable that detector 30 is disposed especially on the connection portion between movable frame 25 and the first vibrating portion. As described above, by providing detector 30 so as to contain the boundary between first vibrating portion 24 and movable frame 25, a sufficiently strong distortion signal is obtained regardless of the position where first vibrating portion 24 is connected with movable frame 25. However, providing detector 30 on the connection portion causes an obtained signal to contain displacement information about first vibrating portion 24 as well as that about movable frame 25. In this regard, the vibration frequency of displacement of first vibrating portion 24 is in a high-speed range (tens of kilohertz) and is different from that of movable frame 25 with respect to fixed frame 22 in a low-speed range (tens of hertz). For this reason, using a frequency separation filter and the like provides only displacement information about movable frame 25 with respect to fixed frame 22.

It is necessary only that detector 30 is disposed on at least one of the pair of first vibrating portions 24; however, to obtain a stronger distortion signal, detectors 30 are preferably disposed on both ends of movable frame 25. FIG. 7 illustrates deformation of movable frame 25 while actuator 21 is being driven. Deformation of movable frame 25 while actuator 21 is being driven causes both ends of movable frame 25 where detectors 30 are provided to be deformed in the reverse directions. More specifically, when movable frame 25 is deformed so as to project upward, detector 30 is deformed so as to be compressed and when movable frame 25 is deformed so as to project downward, detector 30 is deformed so as to be extended. Accordingly, when movable frame 25 rotates, the pair of detectors 30 are deformed in the reverse directions (extended and compressed) as shown in FIG. 7. For this reason, distortion signals obtained from this deformation have the signal components to be in opposite phases, and when the signals are composited, each of the signals cancels the other. However, using a differential amplifier circuit and the like provides a large output signal.

Note that using detector 30 allows detecting displacement of first vibrating portion 24 as well. To obtain displacement information about movable frame 25, a distortion signal produced when detector 30 is bent-deformed along X axis 23 is used. Meanwhile, using a distortion signal produced when detector 30 is bent-deformed or torsion-deformed along Y axis 26 provides displacement information about first vibrating portion 24. Hence, even a single monitor signal detector is capable of obtaining different signals. Obtained signals are separated for only a desired signal by a frequency separation filter such as a low-pass filter. Besides, one of the pair of detectors 30 may be used for detecting displacement of movable frame 25; the other may be used for detecting displacement of first vibrating portion 24.

### Second Exemplary Embodiment

Hereinafter, a description is made of actuator 41 according to a second exemplary embodiment of the present invention, with reference to the drawings.

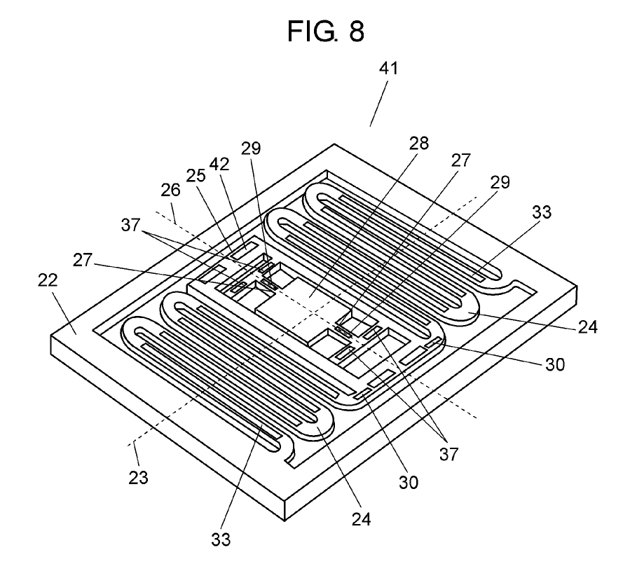

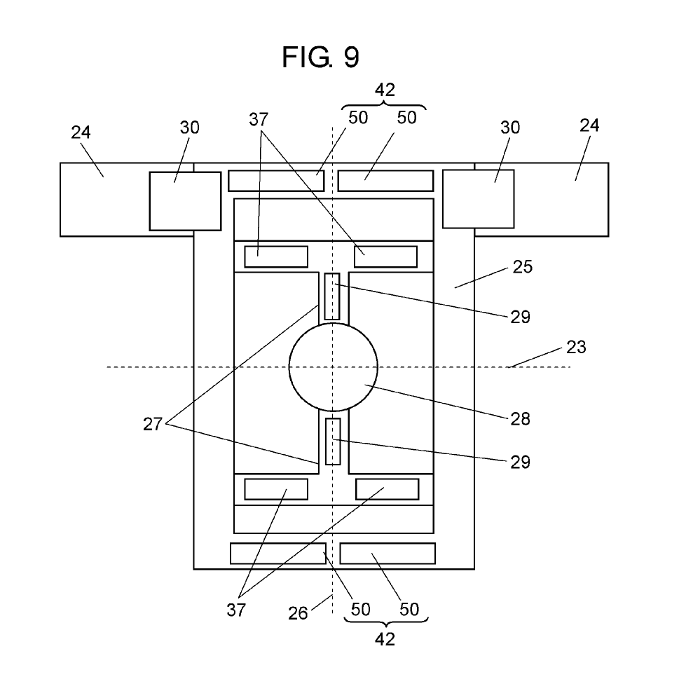

FIG. 8 is a perspective view of actuator 41. FIG. 9 is an enlarged plan view of movable frame 25 and its periphery of actuator 41. Note that actuator 41 has the same structure as that of actuator 21 of the first embodiment, and rotate-drives movable portion 28. Thus, a description is made of only structures different from those of actuator 21. Components same as those of actuator 21 are given the same reference marks for description. Specifically, actuator 41 includes fixed frame 22, a pair of first vibrating portions 24, movable frame 25, a pair of second vibrating portions 27, movable portion 28, first monitor signal detectors (hereinafter, detectors) 30, first drivers 33, and second drivers 37. Actuator 41 further includes third drivers 42 provided on movable frame 25 and capable of controlling displacement of movable frame 25.

Third driver 42, in the same way as first driver 33 shown in FIG. 2, is composed of a lower electrode formed on an insulator on the substrate, a piezoelectric body formed on the lower electrode, and an upper electrode formed on the piezoelectric body. Applying a given electric potential difference between the lower electrode and the upper electrode allows third driver 42 to deform movable frame 25.

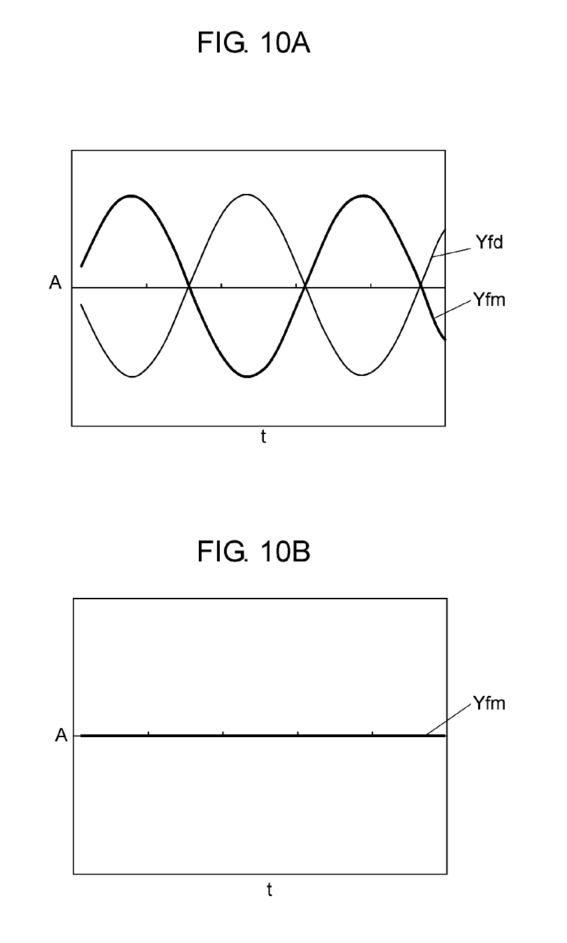

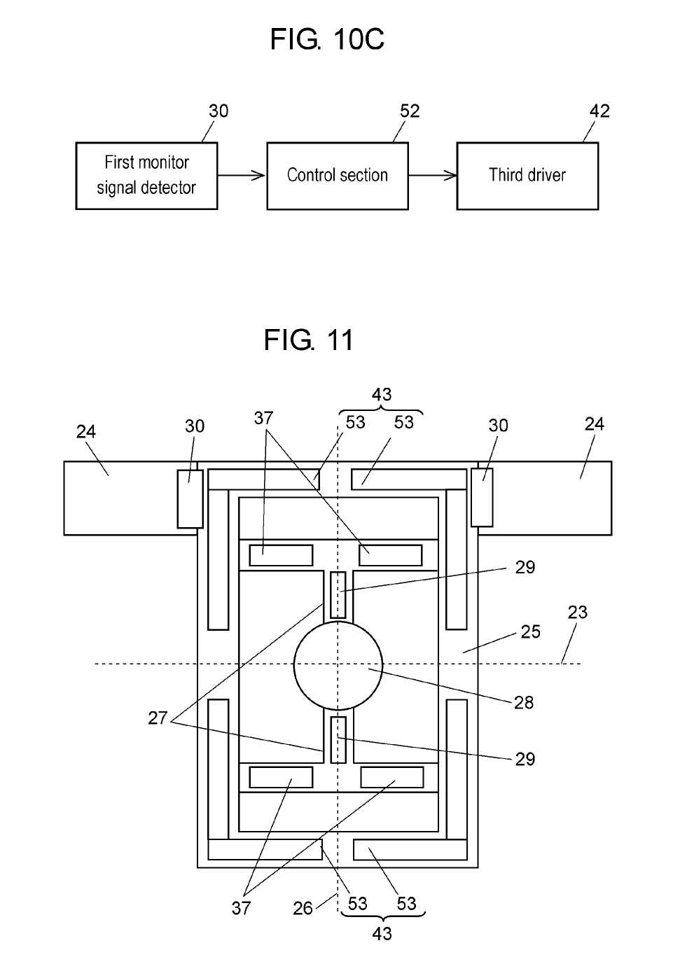

FIG. 10 illustrates drive signal Yfd for damping a signal from movable frame 25, and displacement information Yfm about movable frame 25. FIG. 10B illustrates displacement information Yfm about movable frame 25 with respect to fixed frame 22. When drive signal Yfd is generated on the basis of a signal detected by detectors 30 so that third driver 42 is driven in a phase opposite to that of fluctuation of movable frame 25 and drive signal Yfd is input into third drivers 42, deformation of movable frame 25 is cancelled. This prevents movable frame 25 from fluctuating, thereby keeping the phase difference between movable frame 25 and fixed frame 22 constant, which makes it possible to obtain accurate displacement information about movable portion 28. This signal process can be performed by a circuit provided outside actuator 41. Alternatively, as shown in FIG. 10C, actuator 41 may be provided thereon with control section 52 which generates drive signal Yfd with a phase opposite to that of a signal obtained from detectors 30 and inputs the signal into third drivers 42.

When displacement information Yfm about movable frame 25 obtained from detectors 30 is represented by formula (4), drive signal Yfd, represented by formula (5) and to cancel this fluctuation having the opposite phase, is generated and is input into third drivers 42 provided on movable frame 25.

Yfm=C sin(ωt+δf) (4)

Yfd=−D sin(ωt+δf) (5)

Beside, by forming a feedback circuit that adjusts amplitude D of an input signal so that amplitude C of displacement information Yfm approaches zero to an extreme extent, deformation of movable frame 25 is cancelled, the phase difference between movable frame 25 and fixed frame 22 is kept constant as shown in FIG. 10B.

As described above, by controlling a signal to be input into third drivers 42 so that amplitude C of displacement information Yfm approaches zero to an extreme extent, accurate displacement information about movable portion 28 can be obtained. By controlling actuator 41 according to this information, high-resolution images can be displayed without a phase shift even for a case of synchronization with an image signal for example.

As shown in FIG. 9, it is preferable that each of third drivers 42 is provided on the two sides, parallel with X axis 23, of movable frame 25 and each of third drivers 42 is divided and provided symmetrically with respect to Y axis 26.

Third driver 42 may be divided in any way such as dividing only the upper electrode with the piezoelectric body and lower electrode common, and bisecting third driver 42 itself. Third driver 42 in such a structure allows inputting drive signals in opposite phases into the pair of drive pieces 50. Therefore, drive pieces 50 can be driven so as to cancel displacement of movable frame 25, which further reduces fluctuation of movable frame 25. Note that the symmetry axis of third driver 42 can be an axis connecting the centers of the pair of sides, parallel with X axis 23, of movable frame 25, instead of Y axis 26 described above. Here, even if third driver 42 is provided only on one side, parallel with X axis 23, of movable frame 25, the advantages according to the embodiment can be achieved. However, third drivers 42 are preferably provided on the two sides parallel with X axis 23.

Next, a description is made of a different structure of the third driver with reference to FIG. 11. FIG. 11 is an enlarged plan view of movable frame 25 and its periphery of another actuator according to the embodiment.

In the structure shown in FIG. 9, third drivers 42 are provided on the sides parallel to X axis 23, of movable frame 25. In the structure shown in FIG. 11, on the other hand, third drivers 43 extend from the sides parallel to X axis 23 to the sides parallel to Y axis 26 of movable frame 25, and are separately disposed centering around Y axis 26.

Third drivers 43 perform drive in the same way as third drivers 42 provided on the sides along X axis 23, of movable frame 25 shown in FIG. 9. Specifically, the pair of drive pieces 53 composing third drivers 43 are driven in opposite phases so as to cancel fluctuation of movable frame 25. This further reduces fluctuation of movable frame 25, thereby keeping the phase difference between movable frame 25 and fixed frame 22 constant, which provides accurate displacement information about movable portion 28. Further, such a structure provides an output intensity of third driver 43 greater than that of third driver 42 shown in FIG. 9, thereby easily damping vibration of movable frame 25. Furthermore, as shown in FIG. 11, the pair of drive pieces 53 are preferably disposed symmetrically with respect to X axis 23 in movable frame 25.

Note that third driver 43 may be provided on the entire movable frame 25 and separately centering around Y axis 26 (not especially illustrated).

In the first and second embodiments, first vibrating portion 24 is formed in a meandrous shape, but not limited to the shape. Other shapes such as a torsion bar shape and a tuning fork shape provide the same advantages. First vibrating portion 24 and second vibrating portion 27 are driven by the piezoelectric effect; however, other driving ways such as electrostatic drive provide the same advantages.

### INDUSTRIAL APPLICABILITY

A display device including a piezoelectric actuator of the present invention can project clear images onto a screen. Accordingly, the present invention is applicable to a compact projector, a head-mounted display, and an infrared detection element for example.

### REFERENCE MARKS IN THE DRAWINGS

21, 41 actuator
22 fixed frame
23 X axis
24 first vibrating portion
25 movable frame
26 Y axis
27 second vibrating portion
28 movable portion
29 second monitor signal detector (detector)
30 first monitor signal detector (detector)
31 substrate
32 insulator
33 first driver
34 lower electrode
35 piezoelectric body
36 upper electrode
37 second driver
42, 43 third driver
50, 53 drive piece
51, 52 control section

1. An actuator comprising:
a fixed frame;
a pair of first vibrating portions facing an inside of the fixed frame, each of the first vibrating portions having a first end connected to the inside of the fixed frame and a second end;
a movable frame connected to each of the second ends of the pair of first vibrating portions;
a pair of second vibrating portions facing an inside of the movable frame and extending in a direction orthogonal to a direction in which the pair of first vibrating portions extend, each of the second vibrating portions having a first end connected to the inside of the movable frame and a second end;
a movable portion connected to each of the second ends of the pair of second vibrating portions; and
a first monitor signal detector provided at a connection portion between the movable frame and at least one of the pair of first vibrating portions, and capable of detecting displacement of the movable frame.

2. The actuator according to claim 1, wherein the first monitor signal detector includes a boundary between the movable frame and one of the pair of first vibrating portions.

3. The actuator according to claim 1, further comprising second monitor signal detectors provided at the pair of second vibrating portions, respectively, and capable of detecting a drive mode of the pair of second vibrating portions.

4. The actuator according to claim 3, further comprising:
drivers provided at the pair of second vibrating portions, respectively, and configured to control displacement of the pair of second vibrating portions; and
a control section configured to generate a drive signal to be input into the driver, based on a signal obtained by compositing a detection signal from the first monitor signal detector and a detection signal from the second monitor signal detector.

5. The actuator according to claim 1, further comprising a driver provided at the movable frame and configured to control displacement of the movable frame.

6. The actuator according to claim 5, further comprising a control section configured to generate a drive signal and input the drive signal into the driver, with the drive signal having a phase opposite to a phase of a signal obtained from the first monitor signal detector.

7. The actuator according to claim 5, wherein the driver is formed of a pair of drive pieces disposed symmetrically with respect to a rotation axis of the second vibrating portions.

8. The actuator according to claim 1, wherein each of the pair of first vibrating portions is formed in a meandrous shape.
